(19) United States
(12) Patent Application Publication
(10) Pub. No.: US 2025/0309920 A1
(43) Pub. Date: Oct. 2, 2025

(54) POWER DISTRIBUTION NETWORK NOISE COMPENSATION TO REDUCE DATA DEPENDENCY JITTER

(71) Applicant: QUALCOMM Incorporated, San Diego, CA (US)

(72) Inventors: Yu HUANG, San Diego, CA (US); Zhi ZHU, San Diego, CA (US); Xiaohua KONG, San Diego, CA (US); Zhiqin CHEN, San Diego, CA (US); Yu SONG, San Diego, CA (US); Chiu Keung TANG, San Diego, CA (US); Miao LI, San Diego, CA (US)

(21) Appl. No.: 18/622,493

(22) Filed: Mar. 29, 2024

(51) Int. Cl. H03M 9/00; H03M 13/27

(52) U.S. Cl. CPC H03M 9/00; H03M 13/27

(57) ABSTRACT

A transmitter in an interface circuit includes a first retimer circuit configured to serialize data by interleaving even bits of the data and odd bits of the data into a first bitstream, a second retimer circuit configured to serialize the data by interleaving even bits of the data and inverted versions of the odd bits of the data into a second bitstream, and line driver circuits configured to transmit the first bitstream over a communication link.

### TECHNICAL FIELD

The present disclosure generally relates to input circuits in high-speed interfaces and, more particularly, to suppression of noise affecting power distribution networks.

### BACKGROUND

Electronic device technologies have seen explosive growth over the past several years. For example, growth of cellular and wireless communication technologies has been fueled by better communications, hardware, larger networks, and more reliable protocols. Wireless service providers are now able to offer their customers an ever-expanding array of features and services, and provide users with unprecedented levels of access to information, resources, and communications. To keep pace with these service enhancements, mobile electronic devices (e.g., cellular phones, tablets, laptops, etc.) have become more powerful and complex than ever. Wireless devices may include a high-speed bus interface for communication of signals between hardware components. For example, the high-speed bus interface may be implemented using a Peripheral Component Interconnect Express (PCIe) bus or a universal serial bus (USB). High frequency signals being communicated using the bus interface may experience attenuation, interference and timing drift, thereby tightening timing margins and rendering the high-frequency signals susceptible to errors caused by jitter. There is an ongoing need to reduce the effects of timing errors, including errors related to jitter.

### SUMMARY

Certain aspects of the disclosure relate to systems, apparatus, methods and techniques for suppressing or reducing jitter in a serial interface.

In various aspects of the disclosure, a transmitter in an interface circuit includes a first retimer circuit configured to serialize data by interleaving even bits of the data and odd bits of the data into a first bitstream, a second retimer circuit configured to serialize the data by interleaving even bits of the data and inverted versions of the odd bits of the data into a second bitstream, and line driver circuits configured to transmit the first bitstream over a communication link.

In various aspects of the disclosure, a method for reducing jitter in a serial interface includes serializing data by interleaving even bits of the data and odd bits of the data into a first bitstream, serializing the data by interleaving even bits of the data and inverted versions of the odd bits of the data into a second bitstream, and providing the first bitstream to line driver circuits that are configured to transmit the first bitstream over a communication link.

In various aspects of the disclosure, an apparatus includes means for generating a serialized data bitstream including a multiplexing circuit configured to combine serialized odd bits of data with first serialized even bits of the data, means for generating a serialized compensation bitstream including a multiplexing circuit configured to combine serialized inverted odd bits of the data with second serialized even bits of the data, and means for transmitting the serialized data bitstream over a communication link.

In various aspects of the disclosure, a transmitter in an interface circuit includes a data path having a first retimer circuit configured to serialize data by interleaving even bits of the data and odd bits of the data into a first bitstream, and a first plurality of line driver circuits configured to transmit the first bitstream over a communication link. The transmitter in the interface circuit further includes a compensation path having a second retimer circuit. The second retimer circuit is a replica of the first retimer circuit.

In one aspect, the first retimer circuit includes a first serializer that is configured to serialize the even bits of the data, and a second serializer that is configured to serialize the odd bits of the data. The first retimer circuit may further include a multiplexing circuit configured to generate the first bitstream by combining data bits output by the first serializer and data bits output by the second serializer.

In one aspect, the second retimer circuit is a replica of the first retimer circuit. The second retimer circuit may include replicas of the line driver circuits. The replicas of the line driver circuits may be configured to receive the second bitstream as an input. The interface circuit may be configured to operate in accordance with a Peripheral Component Interconnect Express (PCIe) protocol or universal serial bus (USB) protocol.

### BRIEF DESCRIPTION OF THE DRAWINGS

FIG. 1 illustrates an example of a system-on-a-chip (SOC) in accordance with certain aspects of the present disclosure.

FIG. 2 illustrates an example of a system that employs a multi-channel data communication link.

FIG. 3 illustrates an eye diagram that is generated as an overlay of multiple symbol intervals.

FIG. 4 illustrates an example of a transmitter in a high-speed serial interface that is configured to use a half-rate clock signal.

FIG. 5 illustrates certain examples of noise that may be introduced into a power rail of a power distribution network.

FIG. 6 illustrates an example of a transmitter in a high-speed serial interface that is configured in accordance with certain aspects of this disclosure.

FIG. 7 illustrates certain aspects of the operation of the transmitter illustrated in FIG. 6.

FIG. 8 is a flow diagram illustrating an example of a method for reducing jitter in a serial interface implemented in accordance with certain aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

With reference now to the figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The terms “computing device” and “mobile device” are used interchangeably herein to refer to any one or all of servers, personal computers, smartphones, cellular telephones, tablet computers, laptop computers, notebooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., read only memory (ROM), random access memory (RAM), flash, etc.), and resources (e.g., timers, voltage regulators, oscillators, etc.), any or all of which may be included in one or more cores.

Memory technologies described herein may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

Certain aspects of the disclosure are applicable to input/output (I/O) circuits that provide an interface between core circuits and memory devices. Many mobile devices employ Synchronous Dynamic Random Access Memory (SDRAM), including Low-Power Double Data Rate (DDR) SDRAM, which may be referred to as DDR SDRAM, low-power DDR SDRAM, LPDDR SDRAM or, in some instances, LPDDRx where x describes the technology generation of the LPDDR SDRAM. Later generations of LPDDR SDRAM designed to operate at higher operating frequencies may employ lower voltage levels in the core of an SoC or memory device to mitigate for increased power associated with the higher operating frequencies.

Certain aspects of the disclosure are applicable to circuits that generate, transmit, receive, process and/or propagate differential signals. A differential signal pair comprises two signals that are phase-shifted from each other by 180°. The signals in the differential signal pair may be referred to as complementary signals. The differential signal pair is transmitted over wires, connectors, interconnects or other conductors using voltages of equal voltage magnitude and opposite polarity. A received signal that represents the difference between the differential signal pair can be generated at a receiving device. Common-mode noise affecting wires, connectors, interconnects or other conductors can be expected to induce a near-identical interference signal in the received differential signal pair, and the interference signal is typically cancelled at the receiver and does not affect the received signal. Certain aspects and concepts of this disclosure apply to differential signals and single-ended signals, where single-ended signals are transmitted over a single wire, connector, interconnect or other conductor.

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Certain aspects of this disclosure relate to circuits used in a high-speed serializer-deserializer (SERDES) physical layer (PHY) circuits. Certain circuits are described that can be deployed in the analog front-end (AFE) of a receiver. In one example, some aspects of the disclosure relate to decision-feedback equalizers that include a plurality of decision-feedback circuits in parallel with the data input circuit of a receiving device.

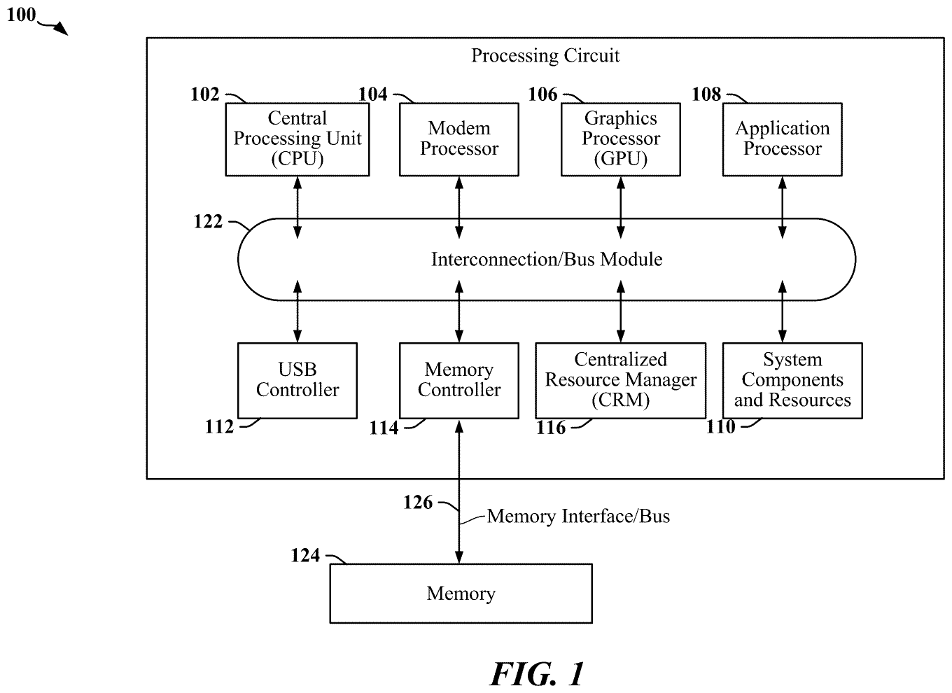

FIG. 1 illustrates example components and interconnections in a system-on-chip (SoC) 100 that may be suitable for implementing certain aspects of the present disclosure. The SoC 100 may include a number of heterogeneous processors, such as a central processing unit (CPU) 102, a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., voltage rails), as well as for more coordinated cooperation between cores.

The SoC 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The SoC 100 may further include a Universal Serial Bus (USB) or other serial bus controller 112, one or more memory controllers 114, and a centralized resource manager (CRM) 116. The SoC 100 may also include an input/output module (not illustrated) for communicating with resources external to the SoC, each of which may be shared by two or more of the internal SoC components.

The processors 102, 104, 106, 108 may be interconnected to the USB controller 112, the memory controller 114, system components and resources 110, CRM 116, and/or other system components via an interconnection/bus module 122, which may include an array of reconfigurable logic gates and/or implement a bus architecture. Communications may also be provided by advanced interconnects, such as high-performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously. The memory controller 114 may be a specialized hardware module configured to manage the flow of data to and from a memory 124 via a memory interface/bus 126.

The memory controller 114 may comprise one or more processors configured to perform read and write operations with the memory 124. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the memory 124 may be part of the SoC 100.

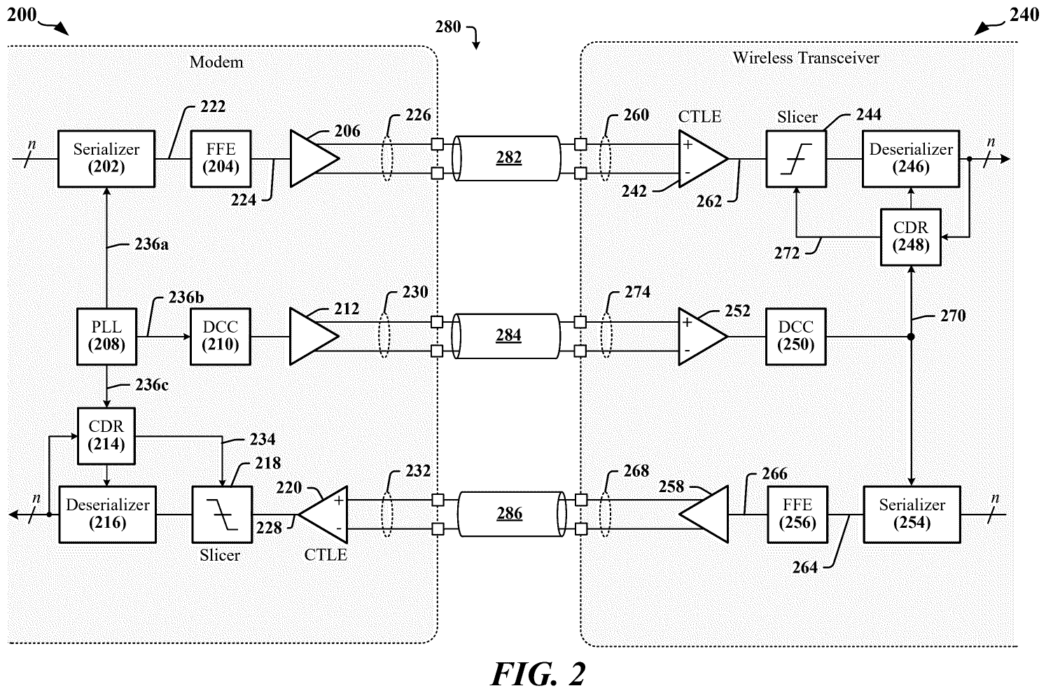

FIG. 2 illustrates an example of a system that employs a multi-channel data communication link 280 to couple a modem 200 with a wireless transceiver 240. The data communication link 280 employs a clock forwarding architecture in which a clock signal is transmitted to provide timing information at the receiver. The illustrated data communication link 280 includes data channels 282 and 286 and a clock channel 284 that provide a transmission medium through which signals propagate between devices. In the illustrated example, a modem 200 transmits data in a first signal over a first data channel 282 to a wireless transceiver 240 and receives data in a second signal transmitted over a second data channel 286. Data signals are transmitted over the data channels 282 and 286 in accordance with timing information provided by a bus clock signal 230 transmitted over the clock channel 284.

The modem 200 may include a serializer 202 configured to convert n-bit parallel data elements, bytes or words into a serial data stream for transmission in a transmit data signal 222 over the first data channel 282. The transmit data signal 222 may be preconditioned by a pre-equalizing circuit, such as the illustrated digital feed-forward equalizer (the FFE 204), in order to combat or compensate for signal distortions attributable to inter-symbol interference (ISI), reflection and other effects that can be expected to limit bandwidth in first data channel 282. The preconditioned transmit data signal 224 output by the FFE 204 is provided to a driver circuit 206 that is configured drive the first data channel 282.

The modem 200 may include a serializer 202 configured to convert n-bit parallel data elements, bytes or words into a serial data stream for transmission in a serialized data signal 222. The serialized data signal 222 may be preconditioned by a pre-equalizing circuit, such as the illustrated digital feed-forward equalizer (the FFE 204), in order to combat or compensate for signal distortions attributable to inter-symbol interference (ISI), reflection and other effects that can be expected to limit bandwidth in the first data channel 282. A preconditioned data signal 224 output by the FFE 204 is provided to a driver circuit 206 that is configured generate and transmit a differential transmit data signal 226 over the first data channel 282.

The wireless transceiver 240 can be configured to process a data signal 260 received over the first data channel 282. The data signal 260 may be provided to a differential receiver 242, which may include or cooperate with an equalizing circuit. In one example, continuous time linear equalization (CTLE) may be used to compensate for certain losses experienced in the first data channel 282. The first data channel 282 may be characterized in some respects as a low-pass filter. In the illustrated example, the differential receiver 242 outputs an equalized data signal 262 that is sampled by a slicer 244. The slicer 244 may be implemented using a D-flipflop or the like and may be configured to capture signaling state of the equalized data signal 262 under the control of edges in a sampling clock signal 272 generated by a clock and data recovery circuit (the CDR circuit 248). The output of the slicer 244 may be provided to a deserializer 246 that is clocked in accordance with one or more clock signals provided by the CDR circuit 248. The CDR circuit 248 may be configured to delay or phase shift a receiver clock signal 270 to ensure that edges in the sampling clock signal 272 are timed to optimize sampling reliability. Additional phases of the receiver clock signal 270 may be generated by the CDR circuit 248 or another circuit to obtain in-phase and quadrature (I/Q) versions of the clock signal to be used by the slicer 244 and/or the deserializer 246. A quadrature signal has phase that is shifted by 90° with respect to an in-phase signal.

In the illustrated wireless transceiver 240, the receiver clock signal 270 is derived from a received bus clock signal 274 over the clock channel 284. A differential receiver 252 coupled to the clock channel 284 may be configured to equalize the received bus clock signal 274, and a duty cycle correction circuit 250 may be used to adjust the duty cycle of the receiver clock signal 270. The receiver clock signal 270 is provided to a serializer 254 that is configured to convert n-bit parallel data elements, bytes or words into a serial data stream for transmission in a serialized data signal 264. The serialized data signal 264 may be preconditioned by a pre-equalizing circuit, such as the illustrated FFE 256, in order to combat or compensate for signal distortions attributable to ISI, reflection and other effects that can be expected to limit bandwidth in the second data channel 286. A preconditioned data signal 266 output by the FFE 256 is provided to a driver circuit 258 that is configured generate and transmit a differential transmit data signal 268 over the second data channel 286.

The illustrated modem 200 can be configured to process a data signal 232 received over the second data channel 286. The data signal 232 may be provided to a differential receiver 220, which may include or cooperate with an equalizing circuit. In one example, CTLE may be used to compensate for certain losses experienced in the second data channel 286. The second data channel 286 may be characterized in some respects as a low-pass filter. In the illustrated example, the differential receiver 220 outputs an equalized data signal 228 that is sampled by a slicer 218. The slicer 218 may be implemented using a D-flipflop or the like and may be configured to capture signaling state of the equalized data signal 228 under the control of edges in a sampling clock signal 234 generated by a CDR circuit 214. The output of the slicer 218 may be provided to a deserializer 216 that is clocked in accordance with one or more clock signals provided by the CDR circuit 214. The CDR circuit 214 may be configured to delay or phase shift a transmitter clock signal to ensure that edges in the sampling clock signal 234 are timed to optimize sampling reliability.

A clock generation circuit, including the illustrated phase locked loop 208, may generate multiple clock signals 236a, 236b, 236c used by the modem 200. One or more of the clock signals 236a, 236b, 236c may be a divided version of a base clock signal generated by the PLL 208. One or more of the clock signals 236a, 236b, 236c may be phase shifted with respect to the base clock signal. In one example, the serializer 202 may produce the serialized data signal 222 using timing provided by a first clock signal 236a. In another example, the bus clock signal 230 transmitted over the clock channel 284 may be derived from a second clock signal 236b. In some instances, a duty cycle correction circuit 210 may be used to adjust the duty cycle of the second clock signal 236b and to provide an input to a driver circuit 212 that is configured drive the clock channel 284. In another example, the CDR circuit 248 may generate the sampling clock signal 234 from a third clock signal 236c.

In high-speed SERDES interfaces, data throughput of a serial data link may be limited by the characteristics of the channel used to carry data signals. Impedance mismatches, parasitic electromagnetic coupling and other factors can cause signal distortion. In many implementations, equalization circuits and capabilities are included in I/O circuits to compensate for signal distortions attributable to inter-symbol interference (ISI) and other effects that can combine to limit bandwidth in a channel. ISI can result when a first-received symbol interferes with subsequently received symbols due to reflections, frequency-dependent delays and other imperfections in the channel. A symbol may refer to signaling state within a unit interval (UI), or symbol interval, in which data is modulated or encoded in the waveform of a transmitted signal. In some instances, a DFE may be implemented in the receiver. The DFE is a nonlinear equalizer that can be configured to flatten channel response and limit signal distortion without introducing noise or crosstalk that can occur with equalizers that operate using amplification of received signals.

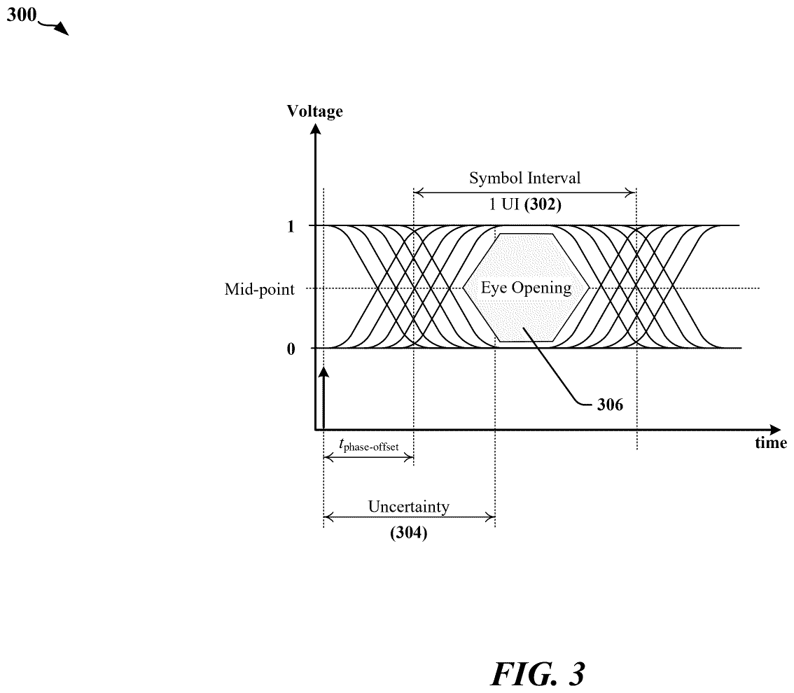

FIG. 3 illustrates an eye diagram 300 generated as an overlay of multiple symbol intervals onto a single symbol interval 302. A signal transition region 304 represents a time period of uncertainty at the boundary between two symbols where variable signal rise times prevent reliable decoding. State information may be determined reliably in a region defined by an eye opening 306 that represents the time period in which the symbol is stable and can be reliably received and decoded. In one example, the eye opening 306 may define a region in which mid-point crossings or other threshold do not occur and a receiver or decoder can reliably sample, demodulate or decode information from a data signal in the symbol interval 302. The eye opening 306 may be narrowed along the time axis by ISI, reflections, increases in data rate, and for other reasons. The eye opening 306 may be compressed in the voltage axis by ISI and other types of interference and distortion.

The concept of periodic sampling and the representation of the signal using an eye diagram can be useful during design, adaptation and configuration of systems which use a clock and data recovery (CDR) circuit that processes a received data-timing signal or that generates a data-timing signal based on frequent transitions appearing in the received data signal. A communication system based on serializer-deserializer (SERDES) technology is an example of a system where an eye opening 306 in an eye diagram 300 can be utilized as a basis for judging the ability to reliably recover data.

Certain SERDES circuits may be operated or controlled by a half-rate clock signal. The term half-rate as used herein refers to the use of a clock signal with a frequency that is half the frequency of the data signal. The use of a half-rate clock signal enables much of the SERDES circuitry to be operated at half the frequency of the data signal, which can relax limits on propagation, setup and hold timing and which significantly reduce power consumption by a communication interface.

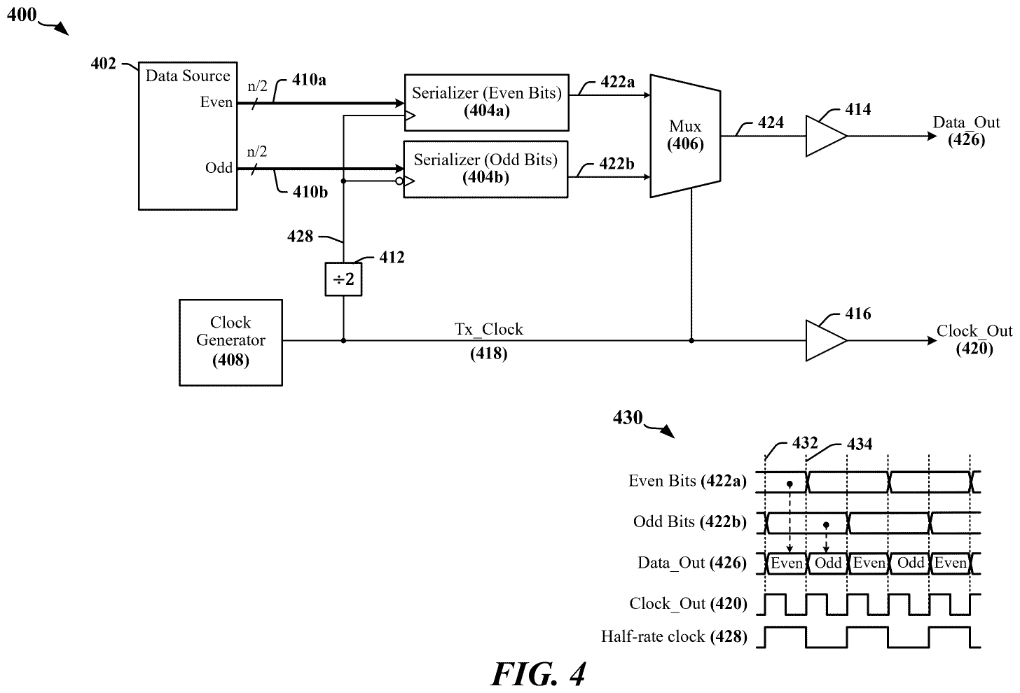

FIG. 4 illustrates an example of a transmitter 400 in a SERDES interface that is configured to use a half-rate clock signal 428. The transmitter 400 provides two transmission paths 410a, 410b that provide bits for transmission in alternating bit transmission intervals. In the illustrated example, data words provided by a data source 402 are split between transmission paths 410a, 410b by even and odd bits. In one example, even bits include bits of a data word that are assigned a weight of 2^{x} and odd bits include bits of a data word that are assigned a weight of 2^{x+1}, where x is an even number and where x≥0. The transmitter 400 alternates between the two transmission paths 410a, 410b when selecting a next bit for transmission.

In the illustrated example, the even bits of a data word are serialized by a first serializer 404a and the odd bits of the data word are serialized by a second serializer 404b. The serializers 404a, 404b are clocked by different types of edges in the half-rate clock signal 428. In one example, the first serializer 404a is clocked by rising edges in the half-rate clock signal 428, and the second serializer 404b is clocked by falling edges in the half-rate clock signal 428. A divider circuit 412 may be used to generate the half-rate clock signal 428 by dividing a transmitter clock signal (the Tx_Clock signal 418) provided by a clock generator circuit 408. In some instances, the Tx_Clock signal 418 is transmitted over a communication link as the Clock_Out signal 420 that is driven by a clock driver circuit 416.

The outputs 422a, 422b of the serializers 404a, 404b may be combined by a multiplexing circuit (the Mux 406) to provide a high-speed serial bitstream 424 with a data rate that corresponds to the frequency of the Tx_Clock signal 418. The timing diagram 430 illustrates certain aspects of the multiplexing of the serializers 404a, 404b. An odd or even bit is added to the serial bitstream 424 in every half-cycle of the half-rate clock signal 428. In one example, circuits in the two transmission paths are clocked by different edges 432, 434 in the half-rate clock signal 428. The Mux 406 is operated at the full-rate frequency to select between outputs of the two transmission paths to provide serial bitstream 424 for transmission over a communication link as the Data_Out signal 426 that is driven by a data driver circuit 414.

The serializers 404a, 404b and other circuits are operated at the frequency of the half-rate clock signal 428 and consume less power than other serializing circuits that operate at the frequency of the Clock_Out signal 420. The Mux 406, the driver circuits 414, 416 and other circuits such as equalizers (not shown) operate at the frequency of the Clock_Out signal 420 with a corresponding power consumption penalty. Furthermore, the driver circuits 414, 416 are expected to drive respective signals 426, 420 with sufficient power to ensure reliable decoding by a receiving device. The changes in current flow in the Mux 406 and the driver circuits 414, 416 at edges of the Clock_Out signal 420 can induce considerable noise in the power distribution network (PDN) of an integrated circuit.

An IC device typically receives power from an external power supply. Examples of external power supplies include batteries, solar cells or solar panels, switching power supplies and other types of power converters. The external power supply may provide power at different voltage levels, where the voltage levels are measured with respect to a ground reference. In one example, the ground reference may be designated to be a zero-volt level. Multiple rails may be provided to carry current to or from the power supply. Each rail provides a low resistance path for current flows and each rail may be implemented using one or more wires, connectors, interconnects, traces on a circuit board or the like. The IC device may be coupled to two or more of the rails and may extend these coupled rails internally using low-impedance interconnects or conductive planes with the IC structure. The internal rails conduct current to the various sections of the IC device at a defined voltage level.

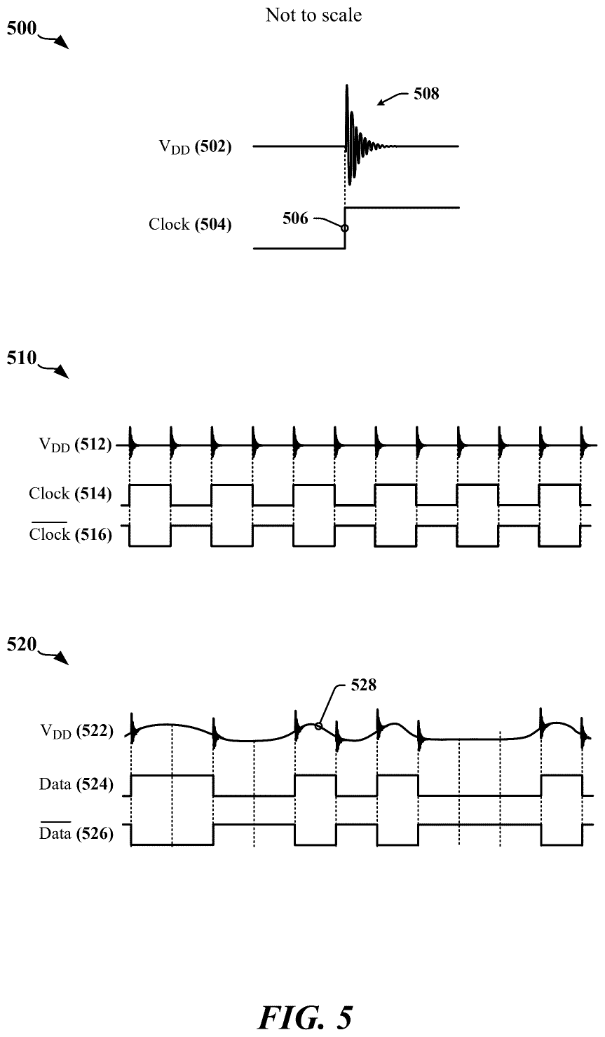

FIG. 5 illustrates certain examples of noise that may be introduced into a power rail of a PDN on an IC device that includes high-speed circuits, such as the transmitter 400 illustrated in FIG. 4. A first timing diagram 500, illustrates a fundamental mechanism by which noise is introduced into the PDN. A clock signal 504 may be characterized as including a time-series of pulses that are transmitted at fixed intervals. Each pulse includes transitions from a low signaling state to a high signaling state and transitions from the high signaling state to the low signaling state. The transitions may be referred to as “edges” herein. The clock signal 504 is propagated through multiple amplifiers and/or multiple layers of transistor switching circuits that are coupled between a power rail (here, the V_{DD} power rail 502) and circuit ground or another power rail. An edge 506 in the clock signal 504 can open and/or close multiple transistors simultaneously, with a resulting current surge. The current surge can induce a spike 508 or impulse in the voltage level of the V_{DD} power rail 502 that decays and/or is suppressed by bypass circuits. In the illustrated example, the spike 508 exhibits ringing whereby the voltage level of the V_{DD} power rail 502 oscillates between a minimum and maximum noise level while decaying.

A second timing diagram 510, illustrates periodic noise that is introduced into a V_{DD} power rail 512 by a clock signal 514. In the illustrated example, the clock signal 514 is propagated through an IC device as a pseudo-differential CMOS signal. The clock signal 514 may be generated, transmitted or received as a single-ended signal and may be amplified, processed or propagated through a circuit as a differential signal. In the second timing diagram 510, an inverted clock signal 516 is shown. The combination of the clock signal 514 and inverted clock signal 516 represents an equivalent differential clock signal, or pseudo-differential clock signal. At every transition, rising and falling edges occur in this differential clock signal and the V_{DD} power rail 512 and the PDN receive the same stimulus at every transition. As illustrated in the second timing diagram 510, each transition in the clock signal 514 induces an effectively identical spike or impulse in the voltage level of the V_{DD} power rail 512 that decays and/or is suppressed by bypass circuits before the next edge in the clock signal 514.

A third timing diagram 520, illustrates two types of periodic noise that are superimposed on a V_{DD} power rail 522 by a data signal 524. The data signal 524 has a data pattern that may be characterized as a pseudorandom binary sequence (PRBS). In the illustrated example, the data signal 524 is propagated through an IC device as a pseudo-differential CMOS signal. The data signal 524 may be generated, transmitted or received as a single-ended signal and may be amplified, processed or propagated through a circuit as a differential signal. In the third timing diagram 520, an inverted data signal 526 is shown. The combination of the data signal 524 and inverted data signal 526 represents an equivalent differential clock signal, or pseudo-differential clock signal. At every transition, rising and falling edges occur in this differential data signal and the V_{DD} power rail 522 and the PDN receive the same stimulus at every transition.

As illustrated in the second timing diagram 510, each edge in the data signal 524 induces a spike or impulse in the voltage level of the V_{DD} power rail 512 that decays and/or is suppressed by bypass circuits before the next edge in the data signal 524. However, the PRBS in the data pattern causes the edges in the data signal 524 to be spaced at irregular intervals and introduces lower frequency components into the data signal 524. Lower frequency components in the data signal 524 can produce an irregular cycle of current flow that may superimpose a lower-frequency waveform 528 on the V_{DD} power rail 522. The waveform 528 may be suppressed using bypass circuits.

Variations in voltage levels of the V_{DD} power rail 522 can cause corresponding variations in switching times of transistors and/or corresponding variations in rise and fall times of signals in transistor-based circuits. These variations in transistor operation can exacerbate or introduce jitter into data signals transmitted through a high-speed interface. The term jitter may be used to describe deviations from the nominal periodicity of a signal. Jitter may exhibit in data signals as deviations from nominal timing of edges or transitions between signaling states. Combinations of resistance, inductance and capacitance (RLC) in an IC device can be a primary source of jitter. Jitter can limit the maximum data rate of a communication link.

In some instances, jitter caused by PDN noise can be reduced by adding decoupling capacitance (deCap) between power rails in an IC device. Increased deCap in a PDN can reduce power supply noise and can reduce transmitter output jitter at the cost of increased area of a semiconductor die that is needed to implement capacitors in the IC device. The reservation of substantial areas of semiconductor die for capacitors provides little operational value when a transmitter circuit is clocked at lower data rates. Furthermore, the reduction in jitter that can be accomplished through added deCap is limited.

In some instances, jitter caused by PDN noise can be reduced when current mode drivers are used in the transmitter circuits instead of voltage mode drivers. Current mode drivers can be relatively tolerant of changes of power supply rails. However, current mode drivers typically consume twice the current that is consumed by comparable voltage mode drivers. The excess current consumption is not justified for lower frequency operation and may be problematic in a transmitter circuit that is designed for use in multiple modes of operation. For example, PCIe specifications for SERDES PHY provide for a wide range of data rates and a PCIe transmitter may be required to operate at frequencies between 1.25 Gbps and 32 Gbps. At the low end of the frequency range, specifications for maximum jitter are relatively loose and PDN noise poses a relatively insignificant problem. In these latter scenarios, the increased current consumption of a current mode driver brings no reciprocal benefit.

Certain aspects of this disclosure relate to techniques and circuits for reducing jitter caused by PDN noise. In one aspect, noise induced by circuits that process or propagate high frequency data signals can be controlled and rendered deterministic. The noise may be rendered deterministic by eliminating or significantly reducing randomness of the noise. A transmitter circuit configured according to certain aspects of this disclosure can ensure that power supply noise induced by step transitions in a data signal are introduced at every possible data signal transition. In some implementations, the effects of power supply noise are invariant and transistors invariably introduce the same delay regardless of the signaling state or change in signaling state of a data signal in the transmitter.

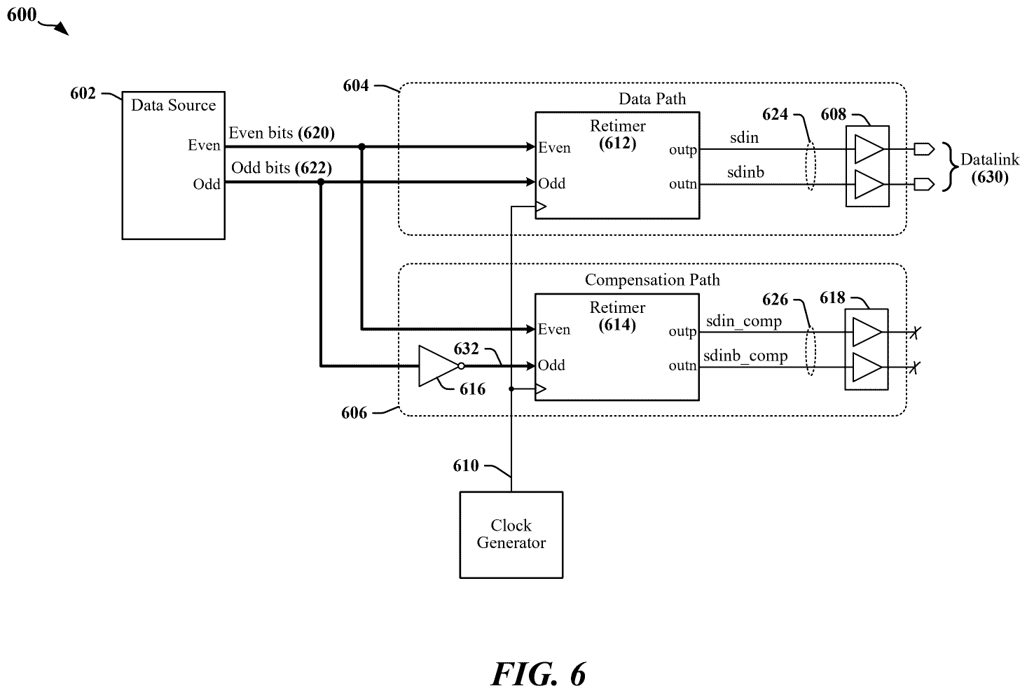

FIG. 6 illustrates an example of a transmitter 600 in a SERDES interface that is configured in accordance with certain aspects of this disclosure. The transmitter 600 provides two transmission paths (the data path 604 and the compensation path 606) that provide bits for transmission in alternating bit transmission intervals. In the illustrated example, data words provided by a data source 602 are split between an even data stream 620 and an odd data stream 622. In one example, even bits provided in the even data stream 620 include bits of a data word that are assigned a weight of 2^{x} and odd bits provided in the odd data stream 622 include bits of a data word that are assigned a weight of 2^{x+1}, where x is an even number and where x≥0. The transmitter 600 alternates between the two data streams 620, 622 when selecting a next bit for transmission.

In the illustrated example, a retimer circuit 612 is provided in the data path 604. The retimer circuit 612 may be configured to generate the two data streams 620, 622 from parallel data received from a data source 602, align the phases of the serialized versions of the two data streams 620, 622, align the align the data streams 620, 622 with one or more internal clock signals used by equalizers or other circuits and/or align the two data streams 620, 622 with a clock signal used to control transmission of data by the SERDES interface. The retimer circuit 612 may include serializers and/or one or more predriver circuits. Predriver circuits may be provided to condition data signals provided as inputs to the line drivers 608. In one example, the line drivers 608 may operate at a voltage level defined for input/output (I/O) circuits and the predriver circuits may be switched by one or more signals generated in a lower-voltage domain. The predriver circuits may receive a data signal from a data source 602 that is resident within the core of an integrated circuit and operated at a core voltage level that is significantly lower than the I/O voltage level. In some implementations, the retimer circuit 612 includes one or more equalizer circuits.

In certain implementations, the even data stream 620 and odd data stream 622 are provided to different serializers (cf. FIG. 4) in the retimer circuit 612. In one example, the serializers are clocked by different types of edges in a half-rate clock signal 610. The retimer circuit 612 may include a multiplexing circuit that provides a high-speed serial data bitstream by interleaving serialized versions of the even data stream 620 and the odd data stream 622. In some examples, the multiplexing circuit corresponds to the Mux 406 illustrated in FIG. 4. The retimer circuit 612 may include circuits that are configured to align the serialized versions of the even data stream 620 and the odd data stream 622 and/or synchronize the high-speed serial data bitstream with the half-rate clock signal 610 or with a transmitter clock signal that controls transmissions over the communication link.

In some examples, a predriver in the retimer circuit 612 may generate a differential output data signal 624 that carries the high-speed serial data bitstream. The output data signal 624 may be provided to line drivers 608 that are configured to drive a pair of wires in a data communication link 630.

The illustrated example includes a retimer circuit 614 that is provided in the compensation path 606. The retimer circuit 614 provided in the compensation path 606 may be a replica of the retimer circuit 612 provided in the data path 604. The retimer circuit 614 may include serializers and/or one or more predriver circuits. In some implementations, the retimer circuit 614 includes one or more equalizer circuits. The even data stream 620 and an inverted version 632 of the odd data stream 622 are provided to different serializers in the retimer circuit 614. In some implementations, the inverted version 632 of the odd data stream 622 is provided by an inverter 616. In one example, the serializers are clocked by different types of edges in a half-rate clock signal 610. The retimer circuit 614 may include a multiplexing circuit that provides a high-speed serial compensation bitstream by interleaving serialized versions of the even data stream 620 and the inverted version 632 of the odd data stream 622. The retimer circuit 614 may include circuits that are configured to align the serialized versions of the even data stream 620 and the inverted version 632 of the odd data stream 622 and/or synchronize the high-speed serial data bitstream with the half-rate clock signal 610 or a transmitter clock signal used to control transmissions over the communication link.

In some implementations, a predriver in the retimer circuit 614 may generate a differential compensation signal 626 that carries the high-speed serial compensation bitstream. The compensation signal 626 may be provided to line drivers 618. The outputs of line drivers 618, if provided, are typically unconnected. In some implementations, the drivers 618 may be omitted from the compensation path 606.

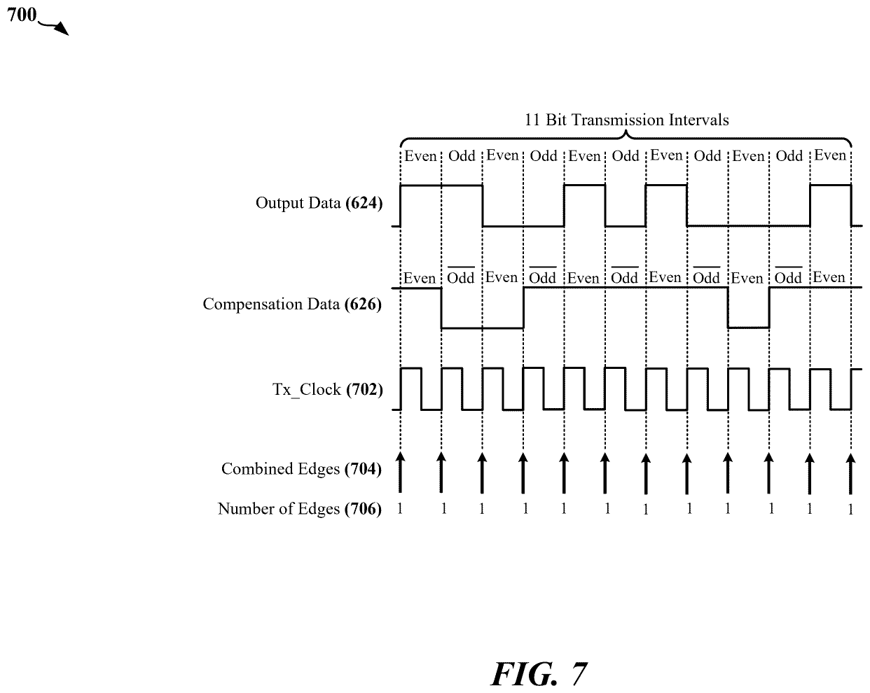

FIG. 7 includes a timing diagram 700 that illustrates certain aspects of the operation of the transmitter 600 illustrated in FIG. 6. The timing diagram 700 covers eleven bit transmission intervals and illustrates an example corresponding to a serialized datastream that exhibits PRBS characteristics. The output data signal 624 represents the serialized datastream provided by interleaving serialized versions of the even data stream 620 and the odd data stream 622. The compensation signal 626 represents the serialized datastream provided by interleaving serialized versions of the even data stream 620 and an inverted version 632 of the odd data stream 622. Edges do not occur in both the output data signal 624 and the compensation signal 626 at any transition between even and odd bit transmission intervals. Table 1 shows all possible outcomes at a transition from an even bit transmission interval to an odd bit transmission interval.

TABLE 1
Even to Odd Transition

| | | Inverse | | Compensation |
|---|---|---|---|---|
| Even Bit | Odd Bit | Odd Bit | Data Signal | Signal |
| 0 | 0 | 1 | No Edge | Edge |
| 0 | 1 | 0 | Edge | No Edge |
| 1 | 0 | 1 | Edge | No Edge |
| 1 | 1 | 0 | No Edge | Edge |

Table 2 shows all possible outcomes at a transition from an odd bit transmission interval to an even bit transmission interval.

TABLE 2
Odd to Even Transition

| | Inverse | Even | | Compensation |
|---|---|---|---|---|
| Odd Bit | Odd Bit | Odd Bit | Data Signal | Signal |
| 0 | 1 | 0 | No Edge | Edge |
| 0 | 1 | 1 | Edge | No Edge |
| 1 | 0 | 0 | Edge | No Edge |
| 1 | 0 | 1 | No Edge | Edge |

The combined outcomes illustrated in Table 1 and Table 2 are shown as combined edges 704 in FIG. 7, along with the number of edges 706 that occur at each transition between bit transmission intervals. The data path 604 and compensation path 606, in combination, produce one and only one edge at each transition between bit transmission intervals. Stated differently, the combination of the circuits in the data path 604 and compensation path 606 produce one and only one edge for each cycle of a transmission clock signal (the Tx_Clock signal 702).

The unpredictability of current or voltage surges due to transistor switching may be eliminated or substantially reduced in the transmitter 600. The circuits in the compensation path 606 can be implemented as replicas of corresponding circuits within the data path 604. The circuits in the data path 604 and the compensation path 606 can be expected to produce near-identical behavior when an edge is generated within their respective circuits at the transition between consecutive bit transmission intervals. The outcomes illustrated in Table 1 and Table 2 illustrate that one, and only one of the two data paths 604, 606 process an edge within each transmission clock cycle such that a near-identical surge in current or voltage can be expected.

In the illustrated example of the transmitter 600, the power supply noise attributable to switching based on edges in a data signal can be expected to resemble the noise generated by a clock signal, which is illustrated in the second timing diagram 510 of FIG. 5. The effect of periodic spikes or impulse (cf. the spike 508 illustrated in FIG. 5) in the voltage level of a power rail can be expected to have consistent and predictable effects on timing of signals generated within or propagated through the transmitter 600. Edges in data signals that exhibit PRBS characteristics can be expected to be delayed or advanced by a consistent degree, thereby reducing jitter.

In one aspect of this disclosure, and with reference again to FIG. 3, the eye opening 306 associated with the data signal 624 may increase when power supply noise caused by processing or generating the data signal 624 is periodic and/or deterministic. The duration of the signal transition region 304 associated with periodic noise may be reduced with respect to the signal transition region 304 associated with noise introduced by PRBS data signals.

In some implementations, the noise added to a power supply rail by the operation of the transmitter 600 can be reduced by adding decoupling capacitance optimized for the frequencies associated with the added noise. The consistent periodicity of the noise establishes a minimum frequency to be targeted for decoupling.

In some implementations, the compensation path 606 includes line drivers 618 that serve no purpose other than to mimic the operation of the line drivers 608 in the data path 604. The inclusion of the line drivers 618 in the compensation path 606 can have a measurable effect on jitter and/or on the performance of noise decoupling circuits. The line drivers 608, 618 are capable of driving a pair of wires in the data communication link 630 and may draw proportionately greater current than other circuits in the data path 604 and compensation path 606. While the current drawn by the line drivers 618 may be a small percentage (e.g., less than 30%) of the current drawn by all circuits in the compensation path 606, excluding the line drivers 618 from the compensation path 606 can increase jitter. In one example, the exclusion of the line drivers 618 may cause the compensation path 606 to contribute lower amplitude noise to a power rail that the amplitude of noise contributed by the data path 604. The lower amplitude noise may be dissipated more quickly than the higher amplitude noise.

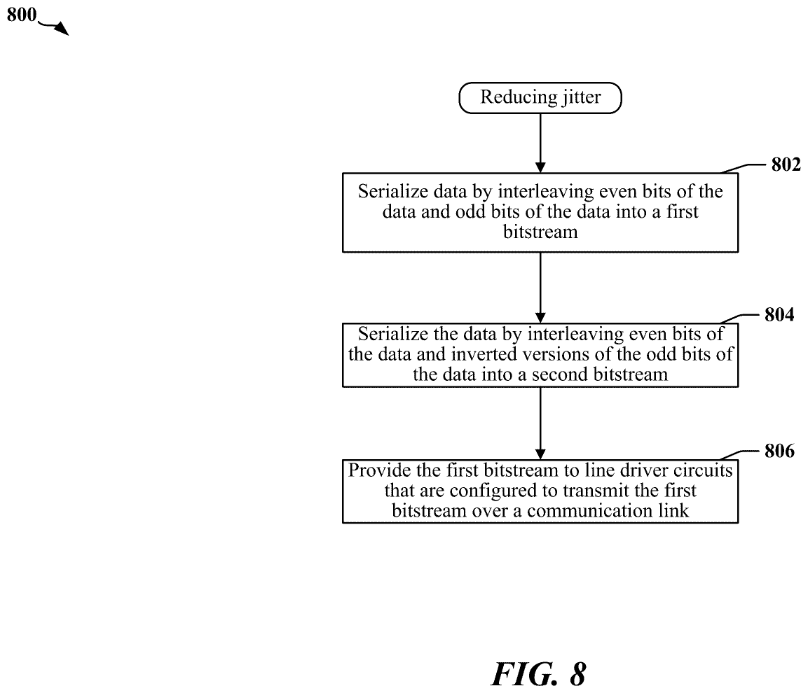

FIG. 8 is a flow diagram 800 illustrating an example of a method for reducing jitter in a serial interface implemented in accordance with certain aspects of this disclosure. The method may be performed using the transmitter 600 illustrated in FIG. 6. At block 802 of the flow diagram 800, data may be serialized by interleaving even bits of the data and odd bits of the data into a first bitstream. At block 804, the data may be serialized by interleaving even bits of the data and inverted versions of the odd bits of the data into a second bitstream. At block 806, the first bitstream may be provided to line driver circuits that are configured to transmit the first bitstream over a communication link.

In certain implementations, a first serializer is configured to serialize the even bits of the data, and a second serializer is configured to serialize the odd bits of the data. A multiplexing circuit may be configured to generate the first bitstream by combining data bits output by the first serializer and data bits output by the second serializer.

In some implementations, the first bitstream is generated by a first retimer circuit and the second bitstream is generated by a second retimer circuit. The second retimer circuit may be a replica of the first retimer circuit. The second retimer circuit may include replicas of the line driver circuits. The replicas of the line driver circuits are configured to receive the second bitstream as an input.

In one implementation, a transmitter in an interface circuit configured in accordance with certain aspects of this disclosure has a first retimer circuit, a second retimer circuit and line driver circuits. The first retimer circuit may be configured to serialize data by interleaving even bits of the data and odd bits of the data into a first bitstream. The second retimer circuit may be configured to serialize the data by interleaving even bits of the data and inverted versions of the odd bits of the data into a second bitstream. The line driver circuits may be configured to transmit the first bitstream over a communication link. The line driver circuits may be coupled to one or more wires of the communication link.

In some instances, the first retimer circuit includes a first serializer that is configured to serialize the even bits of the data, and a second serializer that is configured to serialize the odd bits of the data. The first retimer circuit may further include a multiplexing circuit configured to generate the first bitstream by combining data bits output by the first serializer and data bits output by the second serializer.

In certain examples, the second retimer circuit is a replica of the first retimer circuit. In one example, the second retimer circuit includes replicas of the line driver circuits. The replicas of the line driver circuits may be configured to receive the second bitstream as an input. In one example, the interface circuit may be configured to operate in accordance with a Peripheral Component Interconnect Express (PCIe) protocol. In one example, the interface circuit may be configured to operate in accordance with a universal serial bus protocol.

In another implementation, a transmitter in an interface circuit includes a data path having a first retimer circuit configured to serialize data by interleaving even bits of the data and odd bits of the data into a first bitstream, and a first plurality of line driver circuits configured to transmit the first bitstream over a communication link. The transmitter further includes a compensation path having a second retimer circuit. The second retimer circuit is a replica of the first retimer circuit. In one example, the compensation path further includes a second plurality of line driver circuits that are unconnected to the data communication link. The first timer circuit and the second retimer circuit may be configured to receive a same clock signal from a clock generator. In one example, the compensation path further includes an inverter coupled to an input of the second retimer circuit, the inverter configured to invert the odd bits of the data.

The operational steps described in any of the exemplary aspects herein are described to provide a subset of examples of possible implementations. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

In one example, an apparatus may include means for generating a serialized data bitstream, means for generating a serialized compensation bitstream and means for transmitting the serialized data bitstream over a communication link. The means for generating the serialized data bitstream may include a multiplexing circuit configured to combine serialized odd bits of data with first serialized even bits of the data. The means for generating the serialized compensation bitstream may include a multiplexing circuit configured to combine serialized inverted odd bits of the data with second serialized even bits of the data.

In some implementations, the means for generating the serialized data bitstream includes a first serializer configured to receive even bits of a data word and generate the first serialized even bits of the data, and a second serializer configured to receive odd bits of the data word and generate the serialized odd bits of the data. The multiplexing circuit may be further configured to generate the first bitstream by combining data bits output by the first serializer with data bits output by the second serializer.

In some implementations, the means for generating the serialized compensation bitstream is a replica of the means for generating the serialized data bitstream. The means for transmitting the serialized data bitstream over the communication link may include one or more line driver circuits coupled to an output of the means for generating the serialized data bitstream. The means for generating the serialized compensation bitstream may include replicas of the line driver circuits. The replicas of the line driver circuits may be coupled to an output of the means for generating the serialized compensation bitstream.

Some implementation examples are described in the following numbered clauses:
1. A transmitter in an interface circuit, comprising: a first retimer circuit configured to serialize data by interleaving even bits of the data and odd bits of the data into a first bitstream; a second retimer circuit configured to serialize the data by interleaving even bits of the data and inverted versions of the odd bits of the data into a second bitstream; and line driver circuits configured to transmit the first bitstream over a communication link.
2. The interface circuit as described in clause 1, wherein the first retimer circuit comprises a first serializer that is configured to serialize the even bits of the data, and a second serializer that is configured to serialize the odd bits of the data.
3. The interface circuit as described in clause 2, wherein the first retimer circuit further comprises a multiplexing circuit configured to generate the first bitstream by combining data bits output by the first serializer and data bits output by the second serializer.
4. The interface circuit as described in any of clauses 1-3, wherein the second retimer circuit is a replica of the first retimer circuit.
5. The interface circuit as described in any of clauses 1-4, wherein the second retimer circuit comprises replicas of the line driver circuits.
6. The interface circuit as described in clause 5, wherein the replicas of the line driver circuits are configured to receive the second bitstream as an input.
7. The interface circuit as described in any of clauses 1-6, wherein the interface circuit is configured to operate in accordance with a Peripheral Component Interconnect Express (PCIe) protocol.
8. A method for reducing jitter in a serial interface, comprising: serializing data by interleaving even bits of the data and odd bits of the data into a first bitstream; serializing the data by interleaving even bits of the data and inverted versions of the odd bits of the data into a second bitstream; and providing the first bitstream to line driver circuits that are configured to transmit the first bitstream over a communication link.
9. The method as described in clause 8, wherein a first serializer is configured to serialize the even bits of the data, and a second serializer that is configured to serialize the odd bits of the data.
10. The method as described in clause 9, wherein a multiplexing circuit is configured to generate the first bitstream by combining data bits output by the first serializer and data bits output by the second serializer.
11. The method as described in any of clauses 8-10, wherein the first bitstream is generated by a first retimer circuit and the second bitstream is generated by a second retimer circuit that is a replica of the first retimer circuit.
12. The method as described in clause 11, wherein the second retimer circuit comprises replicas of the line driver circuits.
13. The method as described in clause 12, wherein the replicas of the line driver circuits are configured to receive the second bitstream as an input.
14. A transmitter in an interface circuit, comprising: a data path having a first retimer circuit configured to serialize data by interleaving even bits of the data and odd bits of the data into a first bitstream, and a first plurality of line driver circuits configured to transmit the first bitstream over a communication link; and a compensation path having a second retimer circuit, wherein the second retimer circuit is a replica of the first retimer circuit.
15. The interface circuit of claim 14, wherein the compensation path further comprises a second plurality of line driver circuits that are unconnected to the data communication link.
16. The interface circuit of claim 14, wherein the first timer circuit and the second retimer circuit are configured to receive a same clock signal from a clock generator.
17 The interface circuit of claim 14, wherein the compensation path further comprises an inverter coupled to an input of the second retimer circuit, the inverter configured to invert the odd bits of the data.
18. An apparatus comprising: means for generating a serialized data bitstream including a multiplexing circuit configured to combine serialized odd bits of data with first serialized even bits of the data; means for generating a serialized compensation bitstream including a multiplexing circuit configured to combine serialized inverted odd bits of the data with second serialized even bits of the data; and means for transmitting the serialized data bitstream over a communication link.
19. The apparatus as described in clause 18, wherein the means for generating the serialized data bitstream comprises a first serializer configured to receive even bits of a data word and generate the first serialized even bits of the data, and a second serializer configured to receive odd bits of the data word and generate the serialized odd bits of the data.
20. The apparatus as described in clause 19, wherein the multiplexing circuit is further configured to generate the first bitstream by combining data bits output by the first serializer with data bits output by the second serializer.
21. The apparatus as described in any of clauses 18-20, wherein the means for generating the serialized compensation bitstream is a replica of the means for generating the serialized data bitstream.
22. The apparatus as described in any of clauses 18-21, wherein the means for transmitting the serialized data bitstream over the communication link comprises one or more line driver circuits coupled to an output of the means for generating the serialized data bitstream.
23. The apparatus as described in clause 22, wherein the means for generating the serialized compensation bitstream comprises replicas of the line driver circuits.
24. The apparatus as described in clause 23, wherein the replicas of the line driver circuits are coupled to an output of the means for generating the serialized compensation bitstream.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The present disclosure is provided to enable any person skilled in the art to make or use aspects of the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A transmitter in an interface circuit, comprising:
a first retimer circuit configured to serialize data by interleaving even bits of the data and odd bits of the data into a first bitstream;
a second retimer circuit configured to serialize the data by interleaving even bits of the data and inverted versions of the odd bits of the data into a second bitstream; and
line driver circuits configured to transmit the first bitstream over a communication link.

2. The interface circuit of claim 1, wherein the first retimer circuit comprises a first serializer that is configured to serialize the even bits of the data, and a second serializer that is configured to serialize the odd bits of the data.

3. The interface circuit of claim 2, wherein the first retimer circuit further comprises a multiplexing circuit configured to generate the first bitstream by combining data bits output by the first serializer and data bits output by the second serializer.

4. The interface circuit of claim 1, wherein the second retimer circuit is a replica of the first retimer circuit.

5. The interface circuit of claim 1, wherein the second retimer circuit comprises replicas of the line driver circuits.

6. The interface circuit of claim 5, wherein the replicas of the line driver circuits are configured to receive the second bitstream as an input.

7. The interface circuit of claim 1, wherein the interface circuit is configured to operate in accordance with a Peripheral Component Interconnect Express (PCIe) protocol.

8. A method for reducing jitter in a serial interface, comprising:
serializing data by interleaving even bits of the data and odd bits of the data into a first bitstream;
serializing the data by interleaving even bits of the data and inverted versions of the odd bits of the data into a second bitstream; and
providing the first bitstream to line driver circuits that are configured to transmit the first bitstream over a communication link.

9. The method of claim 8, wherein a first serializer is configured to serialize the even bits of the data, and a second serializer that is configured to serialize the odd bits of the data.

10. The method of claim 9, wherein a multiplexing circuit is configured to generate the first bitstream by combining data bits output by the first serializer and data bits output by the second serializer.

11. The method of claim 8, wherein the first bitstream is generated by a first retimer circuit and the second bitstream is generated by a second retimer circuit that is a replica of the first retimer circuit.

12. The method of claim 11, wherein the second retimer circuit comprises replicas of the line driver circuits.

13. The method of claim 12, wherein the replicas of the line driver circuits are configured to receive the second bitstream as an input.

14. A transmitter in an interface circuit, comprising:
a data path having
a first retimer circuit configured to serialize data by interleaving even bits of the data and odd bits of the data into a first bitstream, and
a first plurality of line driver circuits configured to transmit the first bitstream over a communication link; and
a compensation path having
a second retimer circuit, wherein the second retimer circuit is a replica of the first retimer circuit.

15. The interface circuit of claim 14, wherein the compensation path further comprises a second plurality of line driver circuits that are unconnected to the communication link.

16. The interface circuit of claim 14, wherein the first retimer circuit and the second retimer circuit are configured to receive a same clock signal from a clock generator.

17. The interface circuit of claim 14, wherein the compensation path further comprises an inverter coupled to an input of the second retimer circuit, the inverter configured to invert the odd bits of the data.
